(19) United States
(12) Patent Application Publication
(10) Pub. No.: US 2020/0073187 A1
(43) Pub. Date: Mar. 5, 2020

(54) ARRAY SUBSTRATE, DISPLAY PANEL, AND DISPLAY DEVICE

(71) Applicants: Chongqing HKC Optoelectronics Technology Co., Ltd., Chongqing (CN); HKC Corporation Limited, Shenzhen (CN)

(72) Inventor: Hongyan Chang, Chongqing (CN)

(21) Appl. No.: 16/245,547

(22) Filed: Jan. 11, 2019

Related U.S. Application Data
(63) Continuation of application No. PCT/CN2018/111816, filed on Oct. 25, 2018.

(30) Foreign Application Priority Data
Sep. 3, 2018 (CN) 201811022196.9

(51) Int. Cl. G02F 1/1362; G09G 3/36; G02F 1/1345; H01L 27/12

(52) U.S. Cl. CPC G02F 1/136286; G09G 3/3611; H01L 27/124; G02F 1/1345; G09G 3/3607

(57) ABSTRACT

The present disclosure provides an array substrate, a display panel, and a display device. The display panel includes an array substrate, the array substrate includes: a display unit; a drive unit; a fan out area, located between the display unit and the drive unit, the fan out area defines a fan out wire group, the fan out wire group is configured to connect the display unit and the drive unit; and a virtual line, defined at at least one side of the fan out wire group and adjacent to a fan out wire at the outermost of the fan out wire group.

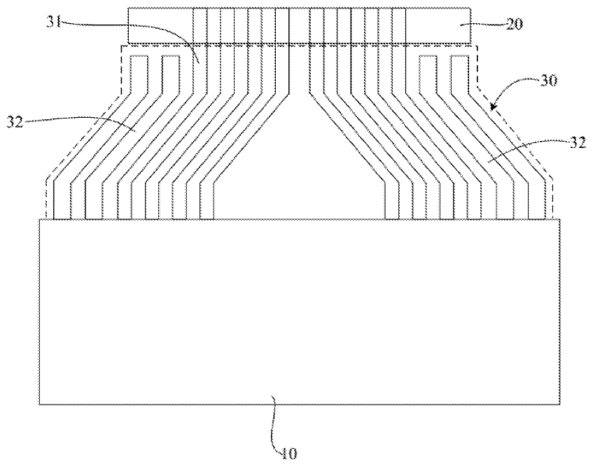

### CROSS REFERENCE TO RELATED APPLICATIONS

The present application is a Continuation Application of PCT Application No. PCT/CN2018/111816 filed on Oct. 25, 2018, which claims the benefit of Chinese Patent Application No. 201811022196.9, filed on Sep. 3, 2018, which is incorporated herein by reference in its entirety.

### FIELD

The present disclosure generally relates to the technical field of display manufacturing, and more particularly relates to an array substrate, a display panel, and a display device.

### BACKGROUND

With the continuous improvement of technology, and increasing demands in liquid crystal display devices, thin film field effect transistor liquid crystal displays have become the mainstream displays in the products, such as mobile phones, flat computers. A liquid crystal display panel includes an array substrate and a color film substrate. For the formations of patterns on the array substrate, each pattern need eight processing steps to finish, including thin film deposition, cleaning, photoresist coating, exposure, development, etching, photoresist stripping, and checking. During the etching process, at the area having a higher wire density the etching solution concentration would decrease, while at the area having a lower wire density the etching solution concentration would increase. Therefore, at an edge area of a fan out wire the etching solution has a higher concentration, which may corrode the edge wire to fracture, causing image signals from a connecting unit cannot be transmitted to a display unit through the fan out area. Therefore, the liquid crystal panel may display images abnormally.

### SUMMARY

The present disclosure provides an array substrate, which aims to solve the problem of how to prevent the liquid crystal panel from abnormally displaying images.

In order to realize the above aim, the array substrate provided by the present disclosure includes:

a display unit;

a drive unit;

a fan out area, located between the display unit and the drive unit, the fan out area defines a fan out wire group, the fan out wire group is configured to connect the display unit and the drive unit; and

a virtual line, defined at at least one side of the fan out wire group and adjacent to a fan out wire at the outermost of the fan out wire group.

Electively, the virtual line is defined at two sides of the fan out wire group, and adjacent to the fan out wire at the outermost of the fan out wire group.

Electively, a portion of the virtual line and a portion of the adjacent fan out wire, which are both located at a same side of the fan out area, are parallel to each other.

Electively, the distance between the virtual line and the adjacent fan out wire at the outermost of the fan out wire group is 3 μm to 8 μm.

Electively, there are a plurality of virtual lines, the multiple virtual lines are spaced from each other along a direction of away from the fan out wire group.

Electively, one end of the virtual line connects an edge of the display unit, the other end of the virtual line is adjacent to the drive unit.

Electively, a distance between the end of the virtual line adjacent to the drive unit, and the drive unit is at least 3 μm.

Electively, a distance between any two adjacent virtual lines is equal to the distance between the virtual line and the adjacent fan out wire.

The present disclosure further provides a display panel, the display panel includes an array substrate, the array substrate includes: a display unit; a drive unit; a fan out area, located between the display unit and the drive unit, the fan out area defines a fan out wire group, the fan out wire group is configured to connect the display unit and the drive unit; and a virtual line, defined at at least one side of the fan out wire group and adjacent to a fan out wire at the outermost of the fan out wire group.

The present disclosure further provides a display device, the display device includes a display panel, the display panel includes an array substrate, the array substrate includes: a display unit; a drive unit; a fan out area, located between the display unit and the drive unit, the fan out area defines a fan out wire group, the fan out wire group is configured to connect the display unit and the drive unit; and a virtual line, defined at at least one side of the fan out wire group and adjacent to a fan out wire at the outermost of the fan out wire group.

For the array substrate of the present disclosure, the virtual line is defined at at least one side of the fan out wire group, and the virtual line is set to be adjacent to the outermost fan out wire of the fan out wire group, the virtual line does not transmit the signal, and the wire structure of the position having the fan out wire located at the edge of the fan out wire group is improved, thus the etching solution concentration of the position is decreased during the etching process, to prevent the fan out wire at the edge of the fan out wire group from being corroded to fracture due to the high etching solution concentration during the etching process. Therefore, the overall stability of the fan out wire group is improved, it can avoid the display panel from occurring the abnormal images due to the fracture of the wire, the stability of the display panel is improved.

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art will now be briefly described, it is evident that the accompanying drawings listed in the following description show merely some embodiments according to this disclosure, and that those having ordinary skill in the art will be able to obtain other drawings based on the arrangements shown in these drawings without making inventive efforts.

The FIGURE is a structure diagram of the array substrate of the present disclosure according to an exemplary embodiment.

### LABELS ILLUSTRATION FOR DRAWINGS

TABLE 1

| Label | Name | Label | Name | Label | Name |
|---|---|---|---|---|---|
| 10 | display unit | 20 | drive unit | 30 | fan out area |
| 31 | fan out wire group | 32 | virtual line | | |

The realization of the aim, functional characteristics, advantages of the present disclosure are further described specifically with reference to the accompanying drawings and embodiments.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It is to be understood that, all of the directional instructions in the exemplary embodiments of the present disclosure (such as top, down, left, right, front, back) can only be used for explaining relative position relations, moving condition of the elements under a special form (referring to figures), and so on, if the special form changes, the directional instructions changes accordingly.

In addition, the descriptions, such as the “first”, the “second” in the present disclosure, can only be used for describing the aim of description, and cannot be understood as indicating or suggesting relative importance or impliedly indicating the number of the indicated technical character. Therefore, the character indicated by the “first”, the “second” can express or impliedly include at least one character. In addition, the “and/or” in the present disclosure means including three paratactic solutions, for example, taking “A and/or B” as an example, the “A and/or B” includes A solution, B solution, or solution of A and B. In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

The present disclosure provides an array substrate.

In the exemplary embodiment of the present disclosure, referring to the FIGURE, the array substrate includes:

a display unit 10;

a drive unit 20;

a fan out area 30, located between the display unit 10 and the drive unit 20, the fan out area 30 defines a fan out wire group 31, the fan out wire group 31 is configured to connect the display unit 10 and the drive unit 20; and

a virtual line 32, defined at at least one side of the fan out wire group 31 and adjacent to a fan out wire at the outermost of the fan out wire group 31.

In the exemplary embodiment, the display unit 10 is configured to display images, the display unit 10 includes a signal line electrically connected with the fan out wire. The drive unit 20 can be a drive chip, which is configured to send display signal to the display unit 10. The drive unit 20 is defined at one side of the display unit 10, there are a plurality of drive units 20, the plurality of the drive units 20 surround the display unit 10 and are spaced from each other. The fan out area 30 is defined between the display unit 10 and the drive unit 20, the fan out area 30 includes the fan out wire group 31, the fan out wire group 31 normally includes a plurality of fan out wires, one end of the fan out wire electrically connects to the signal line of the display unit 10, the other end electrically connects to the drive unit 20, to transmit the display signal of the drive unit 20 to the display unit 10, allowing the display unit 10 to work normally.

The virtual line 32 is defined at at least one side of the fan out wire group 31, as the fan out wire group 31 is located between the display unit 10 and the drive unit 20, thus the virtual line 32 is also located between the display unit 10 and the drive unit 20. The virtual line 32 is adjacent to the fan out wire at the outermost of the fan out wire group 31, the quantity of the virtual line 32 can be one, or plural. If there are a plurality of virtual lines 32, the virtual line 32, in the plurality of virtual lines 32, and closest to fan out wire group 31, is adjacent to the fan out wire at the outermost of the fan out wire group 31. The present disclosure does not limit the position relationship between the virtual line 32 and the fan out area 30, it only needs to set the virtual line 32 to be adjacent to the outermost fan out wire.

The virtual line 32 does not transmit the signal, that is, the virtual line 32 does not electrically connect to the signal line of the display unit 10, nor electrically connect to the drive unit 20, the virtual line 32 just protect the outermost fan out wire. In detail, the virtual line 32 is adjacent to the outermost fan out wire, thus the outermost fan out wire of the fan out wire group 31 is no longer located at the edge of the overall wire structure, that is, the wire density of the position having the outermost fan out wire is improved, and the position having the virtual line 32 is set to have a low wire structure, therefore, during the etching process, the etching solution concentration of the position having the outermost fan out wire would decrease, thus it can avoid the outermost fan out wire from being fractured due to a high etching solution concentration, and the fracture may cause the signal cannot be transmitted normally. However, the etching solution concentration of the position having the virtual line 32 may be higher, as the virtual line 32 only plays a role of protection, even if the virtual line 32 is fractured due to the corrosion, the signal transmission would not be affected. And after the virtual line 32 is fractured, the wire density of the position having the outermost fan out wire would not change, therefore, the virtual line 32 can effectively, and stability protect the outermost fan out wire.

It is to be understood that, as the virtual line 32 play a role of protecting only, therefore, the width and the material of the virtual line 32 can be the same as the width and the material of the fan out wire, thus the array substrates can be centralizedly manufactured, and the production efficiency is improved.

For the array substrate of the present disclosure, at least one side of the fan out wire group 31 defines the virtual line 32, and the virtual line 32 is set to be adjacent to the outermost fan out wire of the fan out wire group, the virtual line 32 does not transmit the signal, and the wire structure of the position having the fan out wire located at the edge of the fan out wire group 31 is improved, thus the etching solution concentration of the position is decreased during the etching process, to prevent the fan out wire at the edge of the fan out wire group 31 from being corroded to fracture due to the high etching solution concentration during the etching process. Therefore, the overall stability of the fan out wire group 31 is improved, it can avoid the display panel from occurring the abnormal images due to the fracture of the wire, the stability of the display panel is improved.

Furthermore, referring to the FIGURE, the virtual line 32 is defined at two sides of the fan out wire group 31, and adjacent to the fan out wire at the outermost of the fan out wire group 31. In the exemplary embodiment, the virtual line 32 is defined at two sides of the fan out wire group 31 to protect the fan out wire at edge parts of two sides of the fan out wire group 31 simultaneously during the etching process, the overall stability of the fan out wire group 31 is further improved, thereby further avoid the liquid crystal panel from abnormally displaying images.

Furthermore, referring to the FIGURE, a portion of the virtual line 32 and a portion of the adjacent fan out wire, which are both located at a same side of the fan out area 30, are parallel to each other. In the exemplary embodiment, one end of the fan out wire extends to the drive unit 20 and electrically connects with the drive unit 20, while the virtual line 32, which cannot transmit the signal, should be avoid from being contacted with the drive unit 20, therefore, the virtual line 32 should be located in the fan out area 20 in its extending direction. The portion of the fan out wire in the fan out area 30 can extend in straight line or folding line, it just needs to set a portion of the virtual line 32 and a portion of the adjacent fan out wire, which are located at the same side of the fan out area 30, to be parallel to each other. A portion of the virtual line 32 and a portion of the adjacent fan out wire, both located at the same side of the fan out area 30, are parallel to each other, as such the distances between portions of the virtual line 32 and corresponding portions of the outermost fan out wire are the same, therefore, the wire densities of the positions respectively having portions of the fan out wire located at the edge of the fan out wire group 31 tends to be the same, as such the etching solution concentrations of different positions are almost the same, to further prevent the fan out wire at the edge of the fan out wire group 31 from being fractured.

Furthermore, the distance between the virtual line 32 and the adjacent fan out wire at the outermost of the fan out wire group 31 is 3 μm to 8 μm. In the exemplary embodiment, it is to be understood that, the quantity of the virtual line 32 can be one, or plural. The distance here is defined as a distance between the virtual line 32 closest to the fan out wire group, and the fan out wire closest to the virtual line 31.

The distance between the virtual line 32 and the outermost fan out wire can be set to be equal to two adjacent fan out wire in parallel, such the wire density of the position of the fan out wires at the edge of the fan out wire group 31 tends to be the same as the overall wire density of the fan out wire group 31. In actual application, the distance between two adjacent fan out wires in parallel can be 3 μm to 8 μm, such the distance between the virtual line 32 and the adjacent fan out wire can be set as 3 μm to 8 μm, the wire density of the position having the fan out wire at the edge of the fan out wire group 31 is controlled reasonably, and the overall stability of the fan out wire group 31 is further improved.

Furthermore, referring to the FIGURE, there are a plurality of virtual lines 32, the plurality of virtual lines 32 are spaced from each other along a direction of away from the fan out wire group 31. In the exemplary embodiment, the present disclosure does not limit the quantity of the virtual line 32, it only needs to satisfy the requirement of that the plurality of virtual lines 32 would not interfere with the other functional units or linear structures on the array substrate. Each two adjacent virtual lines 32 are set to be parallel to each other. The quantity of the virtual line 32 can be set to be plural, to further improve the wire density of the position having the fan out wire at the edge of the fan out wire group 31, the etching solution concentration of the position having the fan out wire at the edge of the fan out wire group 31 is further reduced, as such the fan out wire at the edge of the fan out wire group 31 is effectively and stability protected.

Furthermore, referring to the FIGURE, one end of the virtual line 32 connects an edge of the display unit 10, the other end of the virtual line 32 is adjacent to the drive unit 20. In the exemplary embodiment, the structure of the virtual line 32 can be the same as the structure of the fan out line to facilitate processing. While the virtual line 32 cannot play a role of wire, that is, the end of the virtual line 32 can be contacted with the display unit 10, but the virtual line 32 cannot be electrically connected with the signal line of the display unit 10. One end of the virtual line 32 connects the edge of the display unit 10, to enable the position of the end of the virtual line 32 to be corresponding with the position of the end of the display unit connected with the fan out wire. If the end of the virtual line 32 is too far away from the display unit, the wire density of the position having the end of the fan out wire at the edge of the fan out wire group 31 would not change significantly, which may cause that the etching solution concentration of the position is still too high, and the end of the fan out wire at the position would fracture.

Therefore, the present disclosure can improve the wire density of the position having the end of the fan out wire at the edge of the fan out wire group 31, to reduce the etching solution concentration of the position having the end of the fan out wire at the edge of the fan out wire group 31 during the etching process, the fan out wire at the edge of the fan out wire group 31 can be effectively and stability protected.

The driving unit 20 normally includes the drive chip and the circuit board. In order to avoid the virtual line 32, having the same structure as the fan out wire, from being unintentionally contacted with the drive unit 20 to occur an accident, the other end of the virtual line 32 should be spaced from the drive unit 20 to improve the overall stability of the array substrate.

Furthermore, a distance between the end of the virtual line 32 adjacent to the drive unit 20, and the drive unit 20 is at least 3 μm. In the exemplary embodiment, the virtual line 32 is set to be adjacent to one end of the drive unit 20, and the distance between the virtual line 32 and the drive unit 20 is set to be at least 3 μm, the wire density of the position having the fan out wire located at the edge of the fan out wire group 31 is improved. On the basis of reducing the etching solution concentration of the position having the fan out wire at the edge of the fan out wire group 31 during the etching process, to effectively prevent the virtual line 32 from being contracted with the drive unit 20 unintentionally, the overall stability of the array substrate is improved.

Furthermore, the distance between any two adjacent virtual lines 32 is equal to the distance between the virtual line 32 and the adjacent fan out wire. In the exemplary embodiment, the distance between any two adjacent virtual lines 32 is equal to the distance between the virtual line 32 and the adjacent fan out wire, enabling the overall wire structure, formed by the virtual lines 32 and the fan out wire group 31, to have an much more uniform wire density, thus the concentration of etching solution at the overall wire position is much more uniform during the etching process, the impact on the fan out wire caused by the etching solution is mitigated, as such the overall stability of the fan out wire group 31 is improved, and the overall stability of the array substrate is also improved.

The present disclosure also provides a display panel, the display panel includes an array substrate. The detail structure of the array substrate can be referred to the foregoing exemplary embodiments. As the display panel adopts all the technical proposals of the above exemplary embodiments, the display panel at least has all of the beneficial effects of the technical proposals of the above exemplary embodiments, no need to repeat again.

The present disclosure also provides a display device, the display device includes a display panel. The detail structure of the display panel can be referred to the foregoing exemplary embodiments. As the display device adopts all the technical proposals of the above exemplary embodiments, the display device at least has all of the beneficial effects of the technical proposals of the above exemplary embodiments, no need to repeat again.

The foregoing description merely depicts some embodiments of the present application and therefore is not intended to limit the scope of the application. An equivalent structural or flow changes made by using the content of the specification and drawings of the present application, or any direct or indirect applications of the disclosure on any other related fields shall all fall in the scope of the application.

What is claimed is:

1. An array substrate, wherein, the array substrate comprises:
a display unit;
a drive unit;
a fan out area, located between the display unit and the drive unit, the fan out area defines a fan out wire group, the fan out wire group is configured to connect the display unit and the drive unit; and
a virtual line, defined at at least one side of the fan out wire group and adjacent to a fan out wire at the outermost of the fan out wire group.

2. The array substrate according to claim 1, wherein, the virtual line is defined at two sides of the fan out wire group, and adjacent to the fan out wire at the outermost of the fan out wire group.

3. The array substrate according to claim 1, wherein, a portion of the virtual line and a portion of the adjacent fan out wire, which are both located at a same side of the fan out area, are parallel to each other.

4. The array substrate according to claim 3, wherein, the distance between the virtual line and the adjacent fan out wire at the outermost of the fan out wire group is 3 μm to 8 μm.

5. The array substrate according to claim 1, wherein, there are a plurality of virtual lines, the plurality of virtual lines are spaced from each other along a direction of away from the fan out wire group.

6. The array substrate according to claim 1, wherein, one end of the virtual line connects an edge of the display unit, the other end of the virtual line is adjacent to the drive unit.

7. The array substrate according to claim 6, wherein, a distance between the end of the virtual line adjacent to the drive unit and the drive unit is at least 3 μm.

8. The array substrate according to claim 5, wherein, a distance between any two adjacent virtual lines is equal to the distance between the virtual line and the adjacent fan out wire.

9. The array substrate according to claim 1, wherein, the drive unit is defined at one side of the display unit, and there are a plurality of drive units.

10. The array substrate according to claim 9, wherein, the plurality of drive units surround the display unit and are spaced from each other.

11. The array substrate according to claim 1, wherein, the manufacturing material for the virtual line is the same as the manufacturing material for the fan out wire.

12. The array substrate according to claim 1, wherein, the virtual line and the fan out wire are same in width.

13. The array substrate according to claim 3, wherein, the distance between the virtual line and the outermost fan out wire is equal to the distance between any two adjacent fan out wires which are parallel to each other.

14. The array substrate according to claim 5, wherein, any two adjacent virtual lines are parallel to each other.

15. The array substrate according to claim 1, wherein, the drive unit comprises a circuit board and a drive chip electrically connected with the circuit board.

16. The array substrate according to claim 2, wherein, there are a plurality of virtual lines, the plurality of virtual lines are spaced from each other along a direction of away from the fan out wire group.

17. The array substrate according to claim 3, wherein, there are a plurality of virtual lines, the plurality of virtual lines are spaced from each other along a direction of away from the fan out wire group.

18. The array substrate according to claim 2, wherein, one end of the virtual line connects an edge of the display unit, the other end of the virtual line is adjacent to the drive unit.

19. A display panel, wherein, the display panel comprises an array substrate, the array substrate comprises: a display unit; a drive unit; a fan out area, located between the display unit and the drive unit, the fan out area defines a fan out wire group, the fan out wire group is configured to connect the display unit and the drive unit; and a virtual line, defined at at least one side of the fan out wire group and adjacent to a fan out wire at the outermost of the fan out wire group.

20. A display device, wherein, the display device comprises a display panel, the display panel comprises an array substrate, the array substrate comprises: a display unit; a drive unit; a fan out area, located between the display unit and the drive unit, the fan out area defines a fan out wire group, the fan out wire group is configured to connect the display unit and the drive unit; and a virtual line, defined at at least one side of the fan out wire group and adjacent to a fan out wire at the outermost of the fan out wire group.
